(19) United States
(12) Patent Application Publication
(10) Pub. No.: US 2014/0029891 A1
(43) Pub. Date: Jan. 30, 2014

(54) HERMETIC PACKAGE WITH LEADED FEEDTHROUGHS FOR IN-LINE FIBER OPTIC DEVICES AND METHOD OF MAKING

(71) Applicant: Eigenlight Corporation, Somersworth, NH (US)

(72) Inventors: Craig Douglas Poole, Durham, NH (US); Adam Christian Giroux, Dover, NH (US); Cathy Shaw Trumble, Barrington, NH (US)

(21) Appl. No.: 13/924,890

(22) Filed: Jun. 24, 2013

Related U.S. Application Data
(62) Division of application No. 13/026,388, filed on Feb. 14, 2011, now abandoned.
(60) Provisional application No. 61/337,934, filed on Feb. 12, 2010.

(51) Int. Cl. G02B 6/42; H01L 31/0232

(52) U.S. Cl. CPC G02B 6/4251; H01L 31/02325
USPC 385/14; 438/65

(57) ABSTRACT

An inventive hermetically sealed leaded package for in-line fiber optic devices, such as an optical fiber tap, is described. The package advantageously employs electrical feedthroughs that are compatible with batch processing of micromachined silicon wafers.

### CROSS-REFERENCE TO RELATED APPLICATIONS

This application is a divisional of co-pending U.S. patent application Ser. No. 13/026,388, filed on Feb. 14, 2011, which claims the benefit of U.S. Provisional Patent Application Ser. No. 61/337,934 filed Feb. 12, 2010, which are fully incorporated herein by reference.

### TECHNICAL FIELD

This invention relates to hermetic packaging for fiber optic devices, and particularly to a leaded package for in-line fiber optic devices that provides electrical feedthroughs compatible with batch processing using micromachined silicon wafers.

### BACKGROUND INFORMATION

Fiber optic devices present special challenges to a package designer beyond those encountered with standard electronic packaging. Of particular concern to fiber optics designers are optical feedthroughs that provide optical communication between optical elements inside a package and elements outside of the package. Often such optical feedthroughs use one or more optical fibers that must be reliably secured to the package and at the same time hermetically sealed to prevent ingress of atmospheric moisture that can adversely affect long-term reliability of optical elements inside.

In addition, fiber optic devices often require electrical feedthroughs to allow electrical signals to pass to and from electronic elements within the package. Such electrical feedthroughs are subject to the same requirements of reliability and hermeticity as optical feedthroughs. However, electrical feedthroughs often have many different processing requirements in manufacturing than optical feedthroughs due to differing materials and process temperatures. As such, accommodating both in a manufacturing environment presents a challenge to the fiber optics package designer, in addition to the challenges of achieving ever smaller, lower cost packages.

The term “hermetic” as used herein, indicates impermeability of an enclosed structure to air ingress. However, all enclosed structures are permeable to some degree. Hence, for the purpose of clarity, the term hermetic is used hereinafter to indicate a permeability expressed as a measured helium flow rate into the enclosure of less than 5.times.10.sup.-8 atm-cc/sec, a limit often used with optoelectronic devices.

An in-line fiber optic device, that is where light passes into and out of the package by way of a single, continuous optical fiber, present still further challenges. Examples of in-line devices are the optical fiber taps described in U.S. Pat. Nos. 6,535,671 (issued to Craig D. Poole on Mar. 18, 2003) and 7,116,870 (issued to Craig D. Poole on Oct. 3, 2006), in which a structure is formed directly in midsection of the fiber causing light to be ejected (“tapped”) out of the side of the fiber. In such devices, the well-known method of hermetically sealing a glass fiber by inserting a fiber end into a ferrule that forms a seal around the fiber as described, for example, in U.S. Pat. No. 5,692,086, is not applicable owing to the lack of a terminal fiber end with which to work.

The '671 Poole patent describes a method for hermetically sealing an in-line fiber optic tap inside a housing containing a photodiode by threading the optical fiber through a narrow tube that is then sealed using sealing glass placed between the fiber and tube walls. Since tube diameter must be kept small to minimize stress on the fiber, this method suffers from a need to thread long lengths of optical fiber through narrow tubes when such fiber lengths may exceed 2 meters, consequently rendering this approach impractical for low cost manufacturing.

In order to hermetically seal in-line fiber optic devices, one is thus led to consider a “sandwich” geometry in which two parts are brought together to form a seal around the fiber using some type of sealing material. An example of such an approach is described, in U.S. Pat. No. 6,074,104 (issued to Kimikazu Higashikawa on Jun. 13, 2001). There, a single fiber end is sealed inside a hermetic cavity by sandwiching the fiber between a metal case and metal seal cover using low-temperature glass solder and a resin as the sealing medium.

In addition to providing optical feedthroughs, both the '671 Poole and '104 Higashikawa patents describe packages that include electrical feedthroughs that are connected to leads for mounting the finished packages directly to electronic printed circuit boards. However, both approaches suffer from the use of conventional TO can, DIP or surface-mount electronic packaging that do not lend themselves readily to batch processing methods and require numerous process steps to form the leaded package prior to the sealing of the optical fiber. These approaches are difficult to manufacture at low cost.

Therefore, a need currently exists in the art for a hermetic package for in-line fiber optic devices that includes both optical and electrical feedthroughs, is compatible with batch processing techniques using micromachined silicon wafers and advantageously remedies the above-described deficiencies in the art.

### SUMMARY

The present invention satisfies this need by using a single metal lead structure that is hermetically mounted to a silicon substrate and provides electrical communication with electronic elements inside a sealed cavity, the cavity having been formed by the silicon substrate and a separate silicon sealing cap, through holes etched into the silicon substrate. The metal lead structure has a cylindrically shaped protrusion that extends into the sealed cavity through vertical holes etched in the silicon substrate using deep-reactive ion etching (DRIE). The electrical feedthrough thus formed is sealed using low-temperature sealing glass.

Advantageously, the silicon substrate and sealing cap have complimentary grooves formed therein for hermetically sealing a glass fiber for optical communication with elements within the sealed cavity.

The sealed structure thus formed is further enclosed in a two-piece metal shroud to provide structural support to the sealed structure as well as shielding from electrical noise. The result is a leaded package that can be mounted directly onto a printed circuit board.

In the preferred embodiment of the invention, the package forms an in-line power monitor in which the sealed cavity contains a photodiode that is electrically connected to electrical leads that are in optical communication with an optical fiber such that the electrical current carried by the leads is proportional to the optical power carried by the fiber.

The preferred embodiment further includes spacer beads added to the glass matrix to seal the electrical feedthrough so as to control the spacing between the silicon substrate and the lead structure and thereby control electrical capacitance of the package.

Further, the present inventions teachings extend to a batch process for manufacturing leaded packages using micromachined silicon wafers. The batch process utilizes screen printing techniques to apply glass solder paste on a wafer followed by thermal treatment to burn-out residual organics and glaze the sealing glass. Electrical leads are attached to form hermetic electrical feedthroughs in the silicon wafer prior to dicing the wafer into individual parts. In this way many parts are processed together, thus greatly increasing throughput and lowering its cost.

### BRIEF DESCRIPTION OF THE DRAWINGS

These and other features and advantages will be better understood by reading the following detailed description, taken together with the drawings wherein:

FIG. 1 shows a perspective exploded view of leaded package 100;

FIG. 2 shows a cross-sectional view of a conventional embodiment of leaded package 100 depicted in FIG. 1 the cross-section being taken along a plane indicated by the dashed box in the latter figure;

FIG. 3 shows a cross-sectional view of an embodiment of leaded package 100 depicted in FIG. 1 and according to the present invention, the cross-section being taken in the same manner as for FIG. 2;

FIG. 4 shows a bottom surface of a silicon wafer having an etched pattern according to the present invention;

FIG. 5 shows a perspective view of a lead mounting apparatus according to the present invention; and

FIG. 6 is a perspective view of a top surface of a silicon wafer having etched pattern and electrical leads attached according to the present invention.

To facilitate reader understanding, identical reference numerals are used to denote identical or similar elements that are common to the figures. It is understood that the figures are not drawn to scale.

### DETAILED DESCRIPTION

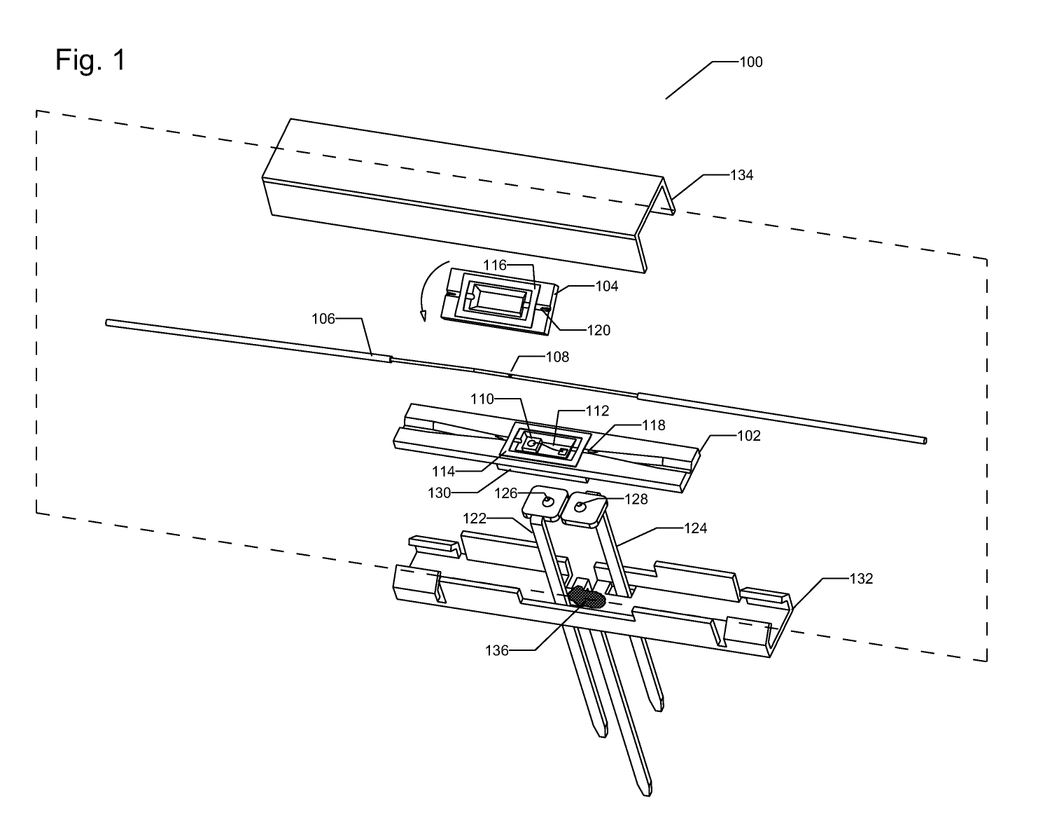

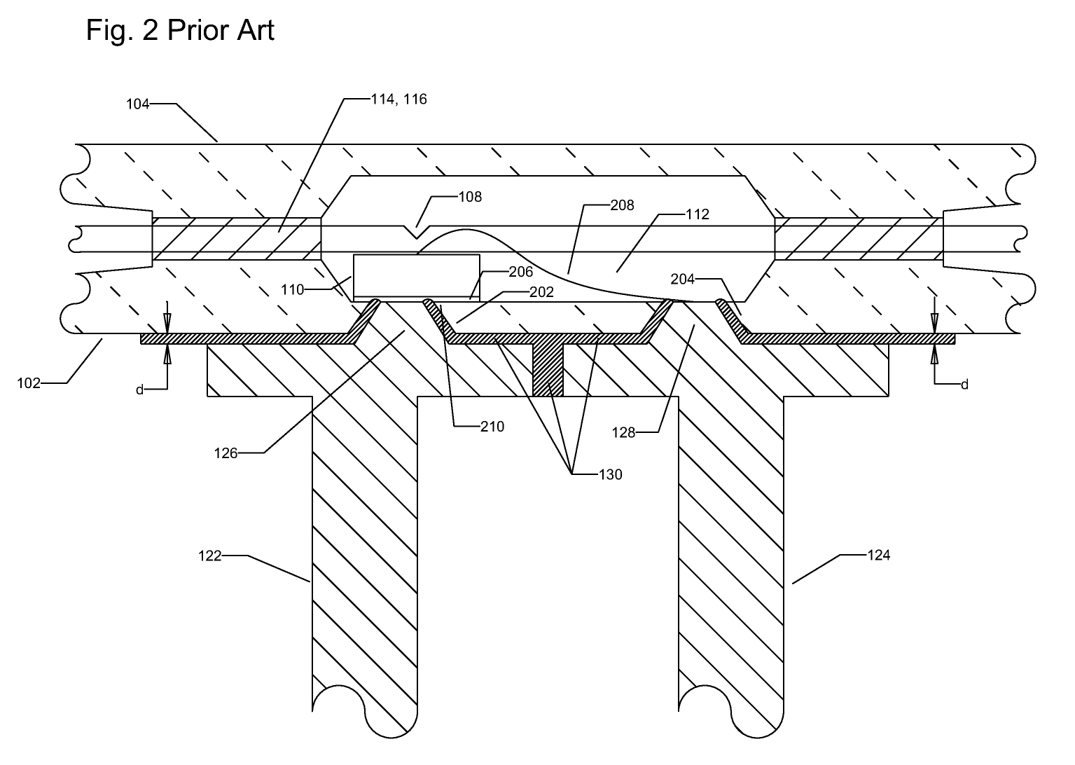

Before describing the interactive hermetic package, to enhance reader understanding, a conventional package for an in-line fiber optic tap will be explained in conjunction with reference to FIGS. 1 and 2.

Referring to the drawings, FIG. 1 shows a perspective view of leaded package 100 having silicon substrate 102, silicon sealing cap 104, optical fiber 106, optical fiber tap 108, and photodiode 110. Photodiode 110 is mounted at the bottom of well 112 that has been formed in silicon substrate 102 using anisotropic wet etching.

Glass solder 114 and 116, and grooves 118 and 120 in silicon substrate 102 and sealing cap 104, respectively, form a hermetically sealed cavity, enclosing optical fiber tap 108, photodiode 110 and well 112, when cap 104 and substrate 102 are brought together under appropriate temperature and pressure so as to cause glass solder 114 and 116 to flow and form a continuous seal.

Prior to sealing, optical fiber tap 108 is positioned above photodiode 110 so that light ejected out of tap 108 efficiently illuminates photodiode 110.

Photocurrent generated by photodiode 110 is carried by leads 122 and 124 which are connected to cathode and anode of photodiode 110, respectively, using protrusions 126 and 128 formed at top of leads 122 and 124. Lead 122 with protrusion 126 and lead 124 with protrusion 128, can each be formed from a single piece of metal, such as “Kovar” material (“Kovar” is a registered trademark of Carpenter Technology Corporation), in a stamping operation. Protrusions 126 and 128 extend up through holes etched through bottom of well 112 and are secured to the bottom of substrate 102 using low-temperature sealing glass 130. A more detailed description of the electrical feedthroughs is provided below.

After sealing, the structure comprising silicon substrate 102, silicon sealing cap 104, and attached leads 122 and 124 is secured to bottom metal shroud 132 using epoxy 136 and subsequently enclosed by adding metal shroud cover 134. Metal shroud cover 134 and bottom metal shroud 132 provide electrical shielding for the enclosed elements in addition to providing mechanical support and protection for handling.

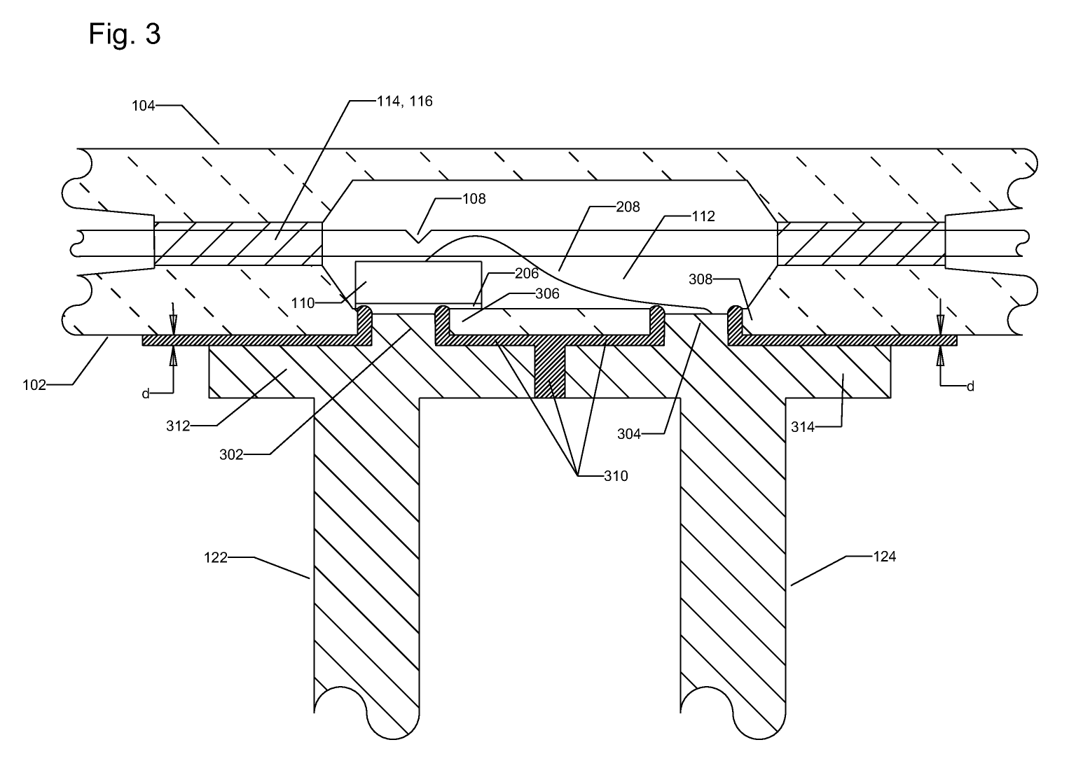

FIG. 2 shows in cross-section a conventional embodiment of leaded package 100 depicted in FIG. 1, with metal shroud cover 134 and bottom metal shroud 132 removed. As noted, the cross-section (as is the case also for FIG. 3) is taken along a plane indicated by the dashed box in FIG. 1. In this embodiment, optical fiber tap 108 is formed in fiber 106 prior to assembly using methods described in the '870 Poole patent. Electrical communication between photodiode 110 and leads 122 and 124 is provided by protrusions 126 and 128 which extend upward through etched holes 202 and 204. Both center well 112 and etched holes 202 and 204 are formed using anisotropic wet etching in a two-step process in which center well 112 is etched first, followed by etched holes 202 and 204 in a secondary etch step. Both center well 112 and etched holes 202 and 204 are substantially square in shape with sloping side walls angled at 54.7 degrees as a result of the anisotropic etching process preferred in single-crystal silicon. Protrusions 126 and 128 have a conical shape with side angles matched to complement those at the sloping walls of etched holes 202 and 204 so as to provide a uniform gap between protrusions 126 and 128 and the wall surfaces of holes 202 and 204. To form a hermetic seal, this gap is filled with low-temperature sealing glass 130. Preferably, sealing glass 130 will be chosen to have a higher melting temperature than glass solder 114 and 116 in order to maintain structural integrity when forming the seal between silicon cap 104 and substrate 102.

Photodiode 110 is connected to protrusions 126 and 128, using conductive epoxy 206 and wire-bond wire 208. Alternatively, a eutectic solder compound such as 80/20 Gold/Tin solder can be used in place of conductive epoxy 206. In order to avoid electrical shorting of protrusions 126 and 128 and photodiode 110 to silicon substrate 102, the surfaces of silicon substrate 102 are coated with an insulating layer of oxide (SiO2) (not shown but well known) prior to assembly.

The conventional electrical feedthroughs shown in FIG. 2 suffer from several problems:

(1) The anisotropic wet etch process necessarily leads to square-shaped through-holes, due to the crystalline structure of the silicon. Such holes have sharp corners that focus stresses causing diminished reliability of the seals.

(2) The sloping walls, angled at 54.7 degrees of etched holes 202 and 204, and center well 112 result in the formation of knife edge 210 where etched holes 202 and 204 enter center well 112. This knife edge and others similarly formed are delicate and have a tendency to crack causing the protective oxide coating to separate from substrate 102 thus shorting the metal leads 122 and 124 to the bulk silicon of substrate 102.

(3) The capacitance of the package is not well controlled due to variability of the glass seal spacing, d, between the metal lead structure and the silicon substrate and which is created when leads 122 and 124 are attached to substrate 102.

FIG. 3 shows, in cross-section, leaded package 100, with a detailed depiction of improved electrical feedthroughs according to the present invention. Electrical communication between photodiode 110 and leads 122 and 124 is provided by protrusions 302 and 304 which extend upward through etched holes 306 and 308. Center well 112 is formed using anisotropic wet etching, with sloping side walls angled at 54.7 degrees again owing to the anisotropic etching process in single-crystal silicon. Etched holes 306 and 308 in silicon substrate 102 are formed using deep-reactive ion etching (DRIE) in a secondary etch step. Etched holes 306 and 308 are cylindrical in shape with a side wall slope of less than 2 degrees. Leads 122 and 124 have protrusions 302 and 304 that have a cylindrical shape with vertical side walls (less than 2 degrees side-wall slope) and a maximum 0.002″ (approximately 0.0051 cm) radius of curvature at the base of the protrusion and can be formed from a single piece of metal, such as Kovar material, in a stamping operation. The diameter of protrusions 302 and 304 is such as to provide a uniform gap between the protrusions and the wall surfaces of holes 306 and 308. Preferably, the diameter of the cylindrical protrusion is nominally 0.012″ (approximately 0.0305 cm). To form a hermetic seal, the gap between protrusions 302 and 304 and between lead structure 312 and 314 and silicon substrate 102 is filled with low-temperature sealing glass 310. Such a long glass-seal path length provides for a hermetic seal and robust mechanical attachment of leads 122 and 124 to silicon substrate 102. Sealing glass 310 contains spacer beads in its glass matrix to control the glass seal spacing, d, between silicon 102 and lead structures 312 and 314 and thereby control the electrical capacitance of the package. Preferably, spacer beads consist of borosilicate glass having a nominal bead diameter of 0.002″ (approximately 0.0051 cm). Spacer beads are added to the glass solder paste in concentrations less than 0.4 wt %. In addition, sealing glass 310 will be chosen to have a higher melting temperature than glass solder 114 and 116 in order to maintain structural integrity when forming the seal between silicon cap 104 and substrate 102.

Photodiode 110 is connected to protrusions 302 and 304, using conductive epoxy 206 and wire bond wire 208. Alternatively, a eutectic solder compound such as 80/20 Gold/Tin solder can be used in place of conductive epoxy 206. In order to avoid electrical shorting of protrusions 302 and 304 and photodiode 110 to silicon substrate 102, the surfaces of silicon substrate 102 are coated with an insulating layer of oxide (SiO2) prior to assembly.

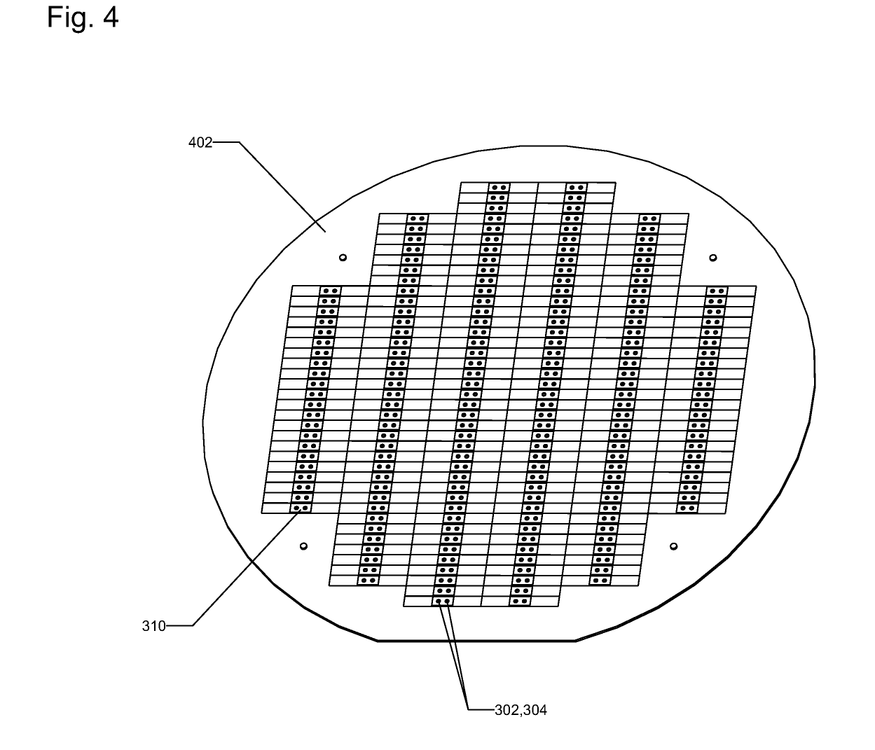

FIG. 4 shows a 100 mm (approximately 4″) micromachined silicon wafer 402 comprised of an array of silicon substrates 102 that have low-temperature sealing glass 310, on its back surface, around holes 302 and 304. Batch processing of silicon wafer 402 is achieved by an anisotropic wet etching of the front surface of the wafer followed by DRIE processing to form holes 302 and 304 on the back surface. Low-temperature sealing glass 310 is applied to the back surface of the wafer around holes 302 and 304 for electrical lead attachment. Preferably, glass solder paste is applied to the wafer using a screen printing process which allows precision placement of the glass solder paste around holes 302 and 304 in a figure-8 pattern followed by thermal treatment to burn-out residual organics and glaze sealing glass 310 in preparation for electrical lead attachment. A double layer screen printing process of the glass solder paste is advantageously used to provide precise control of both thickness of the glass solder paste and its placement around holes 302 and 304.

Although a 100 mm silicon wafer is used in the preferred embodiment, increasing the silicon wafer size to 150 mm (approximately 6″) or 200 mm (approximately 8″) significantly increases the number of parts that can be produced from a single wafer.

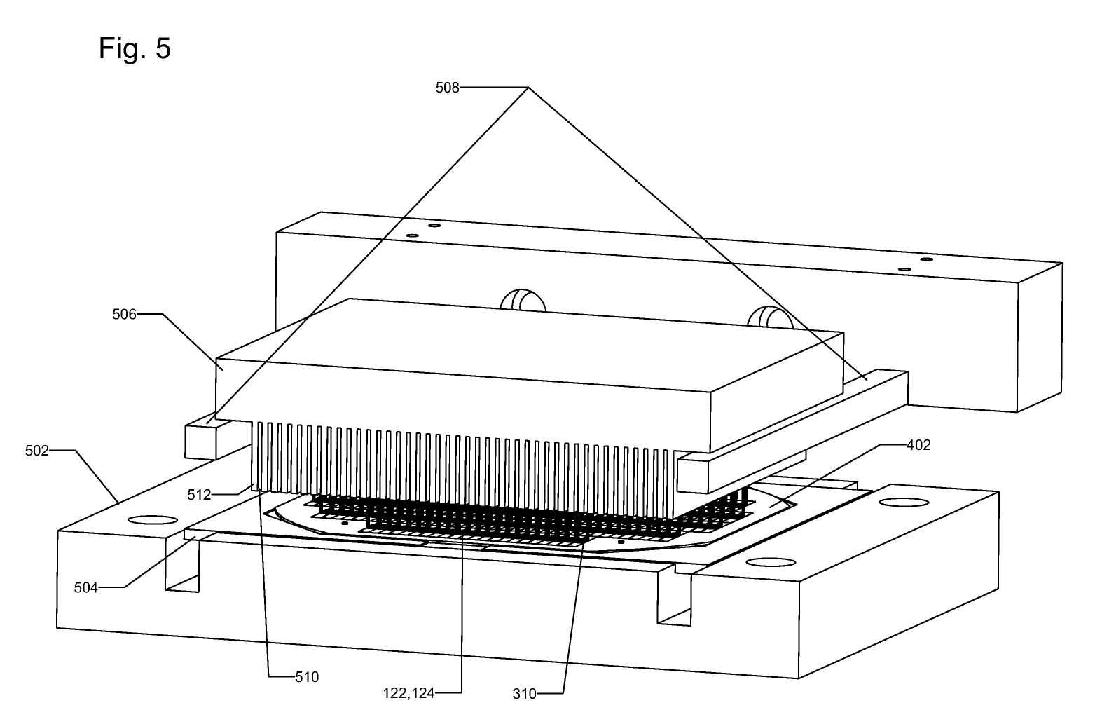

FIG. 5 shows a fixture that has been developed to attach electrical leads 122 and 124 to wafer 402 with low-temperature sealing glass 310 around holes 302 and 304. Prior to placement of the leads, wafer 402 is loaded onto vacuum fixture 502. Vacuum fixture 502 supports wafer 402 and mobile carrier 504 while providing suction to both in order to maximize stabilization during placement of the leads. Comb fixture 506 is supported by separate support arms 508 which move comb fixture 506 relative to wafer 402. Comb fixture 506 has slots 510 precisely machined at regular intervals matching feedthrough hole spacing in wafer 402. With the vacuum turned on, vacuum fixture 502 provides suction through holes 302 and 304 in wafer 402 such that when electrical leads 122 and 124 are placed in position with cylindrical protrusions 302 and 304 in holes 306 and 308, the suction is sufficient to hold the electrical leads in place. An entire row of electrical leads can be properly positioned while the vacuum holds them in place after which comb fixture 506 is advanced by means of support arms 508. Upon advancing comb fixture 506, the leads that have been placed enter into slots 510 where they are enclosed and protected from dislodgement. Vacuum fixture 502, mobile carrier 504, comb fixture 506 and support arms 508 are designed to have appropriate characteristics to allow for precise parallel alignment between slots 510, leads 122 and 124 and wafer 402. After advancing comb fixture 506, a next row of electrical leads can be applied and the process repeated, and so forth. After all the leads are placed over their corresponding holes, comb fixture 506 is lowered by support arms 508 until the entire weight of comb fixture 506 is pressing down on electrical lead structures 312 and 314. The vacuum is then turned off and lead protrusions 302 and 304 positioned in holes 306 and 308, are held in place by a force provided by comb fixture 506 and applied through comb teeth 512 onto lead structures 312 and 314.

Support arms 508 are then used to transport mobile carrier 504, wafer 402, comb fixture 506 and electrical leads 122 and 124, onto a heat source such as a hot plate where the entire assembly is heated to the seal temperature of sealing glass 310. Preferably, this temperature causes sealing glass 310 to flow around protrusions 302 and 304 on the electrical leads to fill the space between the protrusions and hole walls 302 and 304 and the space between lead structure 312 and 314 and silicon 102 forming a hermetic seal between the electrical feedthrough and the silicon substrate. Seal thickness, d, between lead structure 312 and 314 is controlled across the wafer by the presence of spacer beads in sealing glass 310 and the force applied by comb fixture 506 thereby controlling the electrical capacitance of the package.

Because of the high-temperature process involved in attaching leads 122 and 124 to wafer 402, comb fixture 506 should be made of a high-temperature material that is also thermally insulating so as to minimize heat conduction away from silicon wafer 402 and leads 122 and 124 during sealing. An example of such a material is “Macor” machineable ceramic manufactured by Corning Glass Works Corporation (“Macor” is a registered trademark of Corning Glass Works Corporation). Mobile carrier 504 on the other hand should be made of a thermally conductive material such as aluminum nitride so as to efficiently deliver heat to the entire assembly for sealing.

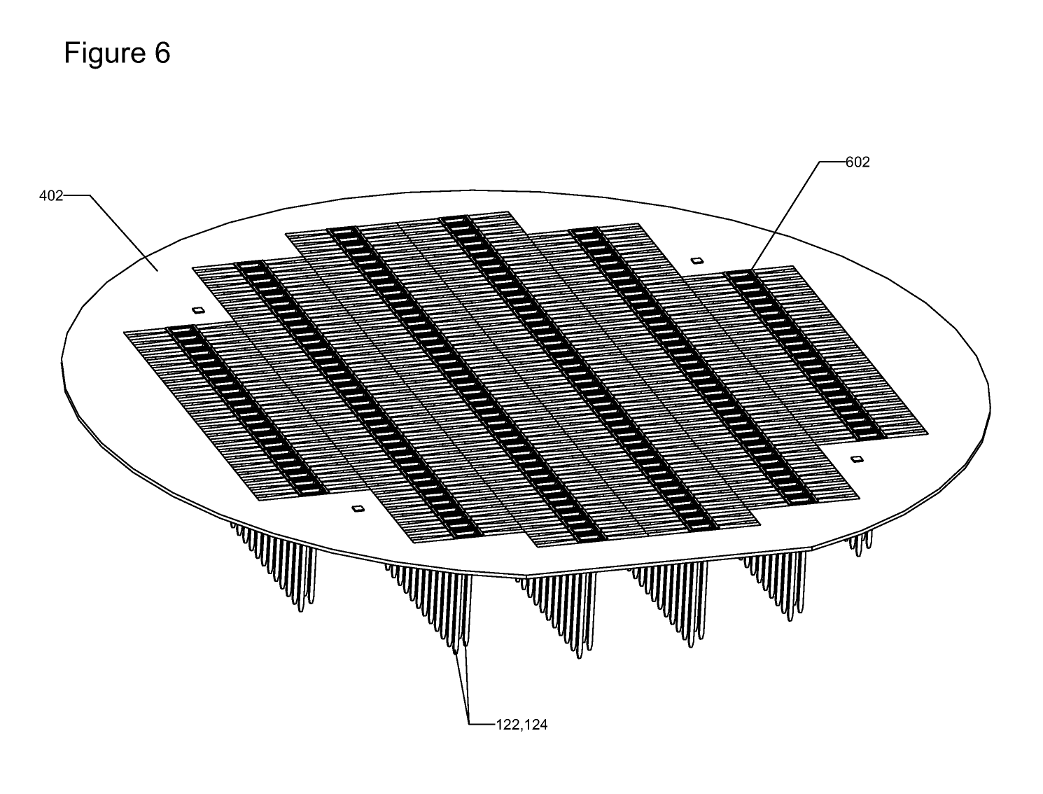

After attaching leads 122 and 124 to the back surface of wafer 402, low-temperature sealing glass 114 is applied to the front surface of wafer 402 around etched well 112, as shown in FIG. 6. Following lead attachment to the backsurface of wafer 402, the wafer is placed on a new mobile carrier designed to accommodate the leads while glass solder paste is screen printed to the front surface of the wafer. This glass solder paste is applied in a race-track pattern around well 112 (see FIGS. 1 and 3) such that groove 118 is also filled with this paste, followed by thermal treatment to burn-out residual organics and glaze sealing glass 114 in preparation for hermetic sealing of silicon cap 104 to substrate 102. The amount of glass solder paste deposited in groove 118 is adjusted by varying the design of the screen used in printing, and by using a double-layer screen printing process. In the preferred embodiment, the race-track pattern of the screen is slightly tapered at a location at groove 118 to alter the amount of glass solder paste that is deposited. The quantity of sealing glass in groove 118 should be sufficient to form a continuous hermetic seal around optical fiber 106 when silicon cap 104 is sealed to substrate 102, but not in excess to impact the optical performance of the device, preferably, sealing glass 114 will be chosen to have a lower melting temperature than sealing glass 310 in order to maintain structural integrity of the leads when forming the seal between silicon cap 104 and substrate 102.

Finally, finished parts are separated from the wafer by dicing. Water is commonly used as a cutting lubricant/coolant during the dicing process. However, low-temperature sealing glass such as those used here is subject to reaction with water during wafer dicing with a diamond saw. In particular, degradation of sealing glass 114 during the dicing process could result in poor sealing of silicon cap 104 to silicon substrate 102 thereby compromising optical performance and hermeticity of the package. Addition of a cutting lubricant, such as L300 offered by UDM Systems of Raleigh, N.C., to the water supply for dicing renders the water less reactive with the sealing glass than would otherwise occur.

Advantageously, the present invention provides a highly reliable hermetic package for in-line fiber optic devices that can be cost-effectively manufactured using wafer-level processing of micromachined silicon and batch processing techniques.

Clearly, those skilled in the art can readily modify the inventive teachings. In that regard, alternative embodiments could use UV laser cutting techniques to form the vertical wall holes in the silicon substrate. Alternatively, glass solder paste could be applied on the wafer-level using robot dispensing of the material, however dispensing techniques would increase wafer processing time and precision placement of the paste around the feedthrough holes would be difficult to maintain across the wafer. In addition, the scale of wafer-level processing could be increased by using larger silicon wafers (e.g., 150 mm or 200 mm diameter approximately 6 and 8″ cm, respectively), thereby dramatically increasing the number of individual parts per wafer. Also, alternative embodiments could protect the sealing glass during the dicing operation of the individual parts through use of alternative methods than use of a cutting lubricant, such as application of a protective coating over the sealing glass prior to dicing followed by removal of the coating after dicing.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. A method of making a plurality of packages for in-line fiber optic devices, the method comprising:
providing a silicon wafer including an array of silicon substrates, each of the silicon substrates including at least one hole and sealing glass around the at least one hole;
securing the silicon wafer;
positioning electrical leads such that protrusions extend from lead structures into the holes in the array of silicon substrates;
positioning a comb fixture such that electrical leads enter slots between comb teeth of the comb fixture and the comb teeth apply a force against the lead structures; and
heating to cause the sealing glass to flow around the protrusions to fill a space between the protrusions and the holes in the array of silicon substrates;

2. The method of claim 1 wherein providing the silicon wafer comprises:
etching a center well in each of the silicon substrates; and
deep-reactive ion etching each of the holes.

3. The method of claim 2 wherein providing the silicon wafer further comprises applying the glass solder around the holes using a double layer screen printing process.

4. The method of claim 2 further comprising applying sealing glass around the center well of each of the silicon substrates.

5. The method of claim 1 wherein each of the holes has a cylindrical shape with less than 2° side-wall slope and the protrusions have a cylindrical shape with less than 2° side-wall slope.

6. The method of claim 1 wherein securing the silicon wafer includes securing the silicon wafer on a vacuum fixture, wherein the vacuum fixture provides suction through the holes sufficient to hold the electrical leads in place when the protrusions are located in the holes.

7. The method of claim 1 further comprising moving the silicon wafer to a heat source with the comb fixture applying the force against the lead structures, and wherein the comb fixture is made of a thermally insulating ceramic material.

8. The method of claim 1 wherein said glass solder contains glass spacer beads to control the spacing between said electrical leads and said silicon substrates.

9. The method of claim 1 further comprising dicing the silicon wafer to separate the silicon substrates.

10. The method of claim 1 wherein the comb fixture has a spacing between the slots equal to a spacing between holes in the silicon substrates.

11. The method of claim 1 further comprising:
positioning electronic elements in center wells of the silicon substrates, respectively;
electrically connecting the electronic elements to the electrical leads, respectively;
optically coupling input and output fibers to the electronic elements, respectively; and
covering the center wells of the silicon substrates with silicon sealing caps, respectively, to form sealed cavities containing the electronic elements, wherein the input optical fiber and the second output optical fiber are sealed between the silicon sealing cap and the silicon substrate.

12. A method of making a package for an in-line fiber optic device, the method comprising:
etching a center well into a silicon substrate;
etching at least one cylindrical hole in the silicon substrate using deep-reactive ion etching, the at least one cylindrical hole having less than 2° side-wall slope;
positioning at least one cylindrical protruding structure of at least one electrical lead in the at least one cylindrical hole, the at least one cylindrical protruding structure having less than 2° side-wall slope; and
filling a space between the cylindrical protruding structure and the cylindrical hole with glass solder.

13. The method of claim 12 wherein said glass solder contains glass spacer beads to control the spacing between said electrical lead and said silicon substrate.

14. A package made according to the method of claim 12 wherein the silicon substrate includes tapered v-grooves for containing and securing an input fiber and an output fiber and includes a center well formed in the substrate, and further comprising:
at least one electronic element located in the center well of the substrate and electrically connected to the at least one electrical lead; and
a silicon sealing cap covering the silicon substrate forming a sealed cavity containing the electronic element, wherein the input optical fiber and the second output optical fiber are sealed between the silicon sealing cap and the silicon substrate.

15. The package of claim 14 wherein the glass solder contains glass spacer beads to control the spacing between the electrical lead and the silicon substrate.

16. The package of claim 15 wherein said glass solder includes said spacer beads in concentrations less than 0.4 wt %.

17. The package of claim 15 wherein the spacer beads consist of borosilicate glass.

18. The package of claim 17 wherein the spacer beads have a nominal bead diameter of 0.002 in.

19. The package of claim 14 wherein the electronic element is a photodiode.
